(19) United States
(12) Patent Application Publication
(10) Pub. No.: US 2009/0075490 A1
(43) Pub. Date: Mar. 19, 2009

(54) METHOD OF FORMING SILICON-CONTAINING FILMS

(75) Inventor: Christian DUSSARRAT, Wilmington, DE (US)

Correspondence Address: AIR LIQUIDE;Intellectual Property, 2700 POST OAK BOULEVARD, SUITE 1800, HOUSTON, TX, 77056, US

(73) Assignee: L'Air Liquite Societe Anonyme pour l'Etude et l'Exploitation des Procedes Georges Claude, Paris CEDEX 07 (FR)

(21) Appl. No.: 12/233,057

(22) Filed: Sep. 18, 2008

Related U.S. Application Data
(60) Provisional application No. 60/973,210, filed on Sep. 18, 2007.

(51) Int. Cl. H01L 21/31

(52) U.S. Cl. 438/787; 438/791; 257/E21.24

(57) ABSTRACT

A method of forming a silicon-containing film comprising providing a substrate in a reaction chamber, injecting into the reaction chamber at least one silicon-containing compound; injecting into the reaction chamber at least one co-reactant in the gaseous form; and reacting the substrate, silicon-containing compound, and co-reactant in the gaseous form at a temperature equal to or less than 550° C. to obtain a silicon-containing film deposited onto the substrate. A method of preparing a silicon nitride film comprising introducing a silicon wafer to a reaction chamber; introducing a silicon-containing compound to the reaction chamber; purging the reaction chamber with an inert gas; and introducing a nitrogen-containing co-reactant in gaseous form to the reaction chamber under conditions suitable for the formation of a monomolecular layer of a silicon nitride film on the silicon wafer.

### CROSS-REFERENCE TO RELATED APPLICATIONS

The present application claims the benefit of U.S. Provisional Patent Application No. 60/973,210 filed Sep. 18, 2007, the disclosure of which is hereby incorporated herein by reference.

### FIELD OF INVENTION

This invention relates generally to the field of semiconductor fabrication, and more specifically to methods of forming silicon-containing films. Still more particularly, the invention relates to methods of forming silicon-containing films using a silicon precursor and a co-reactant in the gaseous form.

### BACKGROUND OF INVENTION

In the front end manufacture of Complementary Metal-Oxide-Semiconductor (CMOS) devices, a passivation film such as silicon nitride (SiN) is formed on the gate electrode of each Metal-Oxide-Semiconductor (MOS) transistor. This SiN film is deposited on the top and side surfaces of the gate electrodes (such as polycrystalline silicon or metallic layers) in order to increase the breakdown voltage of each transistor. Attempts have been made to reduce the temperature deposition of such SiN films, to reach a temperature which is not higher than 400° C. However, SiN films deposited at temperatures below 400° C. usually exhibit poorer film qualities. In order to overcome this issue, it has been proposed to use silicon dioxide (SiO₂) films to reinforce SiN film properties (i.e., “dual spacer”) and thereby make effective electrical barrier layers which may significantly improve the device performance.

SiO₂ films are employed in a variety of functions such as shallow trench insulation (STI) layers, inter layer dielectric (ILD) layers, passivation layers and etch-stop layers. Thus it would be desirable to develop an improved process for deposition of these SiO₂ layers at low temperatures, e.g. below 400° C. In the case of dual spacer applications, the deposition of very thin films (e.g., 20-50 Angstrom (Å) thick) performed at low deposition temperatures (e.g., 300° C.), may not lead to the oxidation of the metal electrode and may be uniform all along the gate. Thus, an atomic layer deposition process is typically suitable for such a requirement. As far as the STI applications are concerned, conformal films may be deposited with high deposition rate (several hundred Å per minute) below 500° C.

In order to achieve a high deposition rate, new molecules may be considered in order to improve the reactivity under the desired deposition conditions, i.e., reactivity between the silicon source, the co-reactant and the substrate surface in a Chemical Vapor Deposition (CVD) and/or an Atomic Layer Deposition (ALD) process. For ALD, one parameter to be considered is the minimum steric hinderance so as to maximize the number of sites on which molecules can react.

### BRIEF DESCRIPTION OF THE DRAWINGS

For a detailed description of the preferred embodiments of the invention, reference will now be made to the accompanying drawings in which:

FIG. 1 is a schematic diagram of a film-forming apparatus used in a film-forming method at the beginning of an inert gas purge step.

FIG. 2 is a schematic diagram of the film-forming apparatus of FIG. 1 at the beginning of a silicon-containing compound gas pulse step.

FIG. 3 is a schematic diagram of the film-forming apparatus of FIG. 1 at the beginning of a co-reactant mixed gas pulse.

FIG. 4 is a side view of a metal oxide transistor (MOS) transistor comprising silicon-containing films.

### SUMMARY

Disclosed herein is a method of forming a silicon-containing film comprising:
a) providing a substrate in a reaction chamber,
b) injecting into the reaction chamber at least one silicon-containing compound;
c) injecting into the reaction chamber at least one co-reactant in the gaseous form; and
d) reacting the substrate, silicon-containing compound, and co-reactant in the gaseous form at a temperature equal to or less than 550° C. to obtain a silicon-containing film deposited onto the substrate.

In some embodiments, the method further comprises a silicon-containing compound wherein the silicon-containing compound comprises an aminosilane, a disiliylamine, a silane, or combinations thereof. The aminosilane may comprise a compound having the formula (R¹R²N)ₓSiH₄₋ₓ wherein R¹ and R² are independently H, C₁-C₆ linear, branched or cyclic carbon chain, or a silyl group such as trimethylsilyl, and x is either 1 or 2. Alternatively, the aminosilane comprises a compound having the formula LₓSiH₄₋ₓ wherein L is a C₃-C₁₂ cyclic amino ligand and x is either 1 or 2. The disilylamine may comprise a compound disilylamines having the formula (SiH₃)₂NR wherein R is independently H, C₁-C₆ linear, or a branched or cyclic carbon chain. The silane may comprise a compound having the formula (SiH₃)ₙR with n comprised between 1 and 4, R being selected from the group consisting of H, N, NH, O, SO₃CF₃, CH₂, C₂H₄, SiH₂, SiH and Si. The co-reactant may comprise an oxygen-containing gas, a nitrogen-containing gas, a gas comprising both oxygen and nitrogen, or a mixture of gases comprising both oxygen and nitrogen. The oxygen-containing gas may comprise ozone, oxygen, water vapor, hydrogen peroxide, or combinations thereof. The nitrogen-containing gas may comprise ammonia, nitrogen, hydrazine, or combinations thereof The mixture of gases may comprise ammonia and oxygen. The co-reactant may comprise nitric oxide.

The method may further comprise generating a co-reactant comprising oxygen or nitrogen radicals wherein generating the co-reactant comprises exposing an oxygen-containing or nitrogen-containing compound to a plasma under conditions suitable for the generation of oxygen or nitrogen radicals. In an embodiment, a plasma is generated in the reaction chamber. In an alternative embodiment radicals are feed to the reaction chamber, generated in the reaction chamber, or both.

The method may further comprise purging the reaction chamber with an inert gas after steps a, b, c, d, or combinations thereof wherein the inert gas comprises nitrogen, argon, helium, or combinations thereof.

The method may further comprise repeating steps b) to d) until the desired silicon-containing film thickness is obtained. The method may further heating the substrate in the reaction chamber after its introduction to the reaction chamber prior to carrying out steps b), c), and/or d) wherein the substrate is heated to a temperature equal to or less than the reaction chamber temperature.

The substrate may comprise a silicon wafer (or SOI) used for the manufacture of semiconductor devices, layers deposited thereon, a glass substrate used for the manufacture of liquid crystal display devices, or layers deposited thereon.

The method may further comprise carrying out steps b), c), or both by discontinued injection of at least one of the compounds and/or gases. The pulsed chemical vapor deposition or atomic layer deposition may be carried out in the reaction chamber.

In an embodiment, simultaneous injection of the silicon-containing compound and the co-reactant in the gaseous form may be carried out in the reaction chamber. In another embodiment, alternate injection of the silicon-containing compound and the co-reactant in the gaseous form is carried out in the reaction chamber. In yet another embodiment, the silicon-containing compound or the co-reactant in the gaseous form is adsorbed on the surface of the substrate prior to the injection of another compound and/or at least one co-reactant in the gaseous form.

The silicon-containing film may be formed at a deposition rate of equal to or greater than 1 Å/cycle and the reaction chamber pressure may be at 0.1 to 1000 torr (13 to 1330 kPa).

In an embodiment, the co-reactant in the gaseous form is a gas mixture comprising oxygen and ozone with a ratio of ozone to oxygen below 20% vol. In an alternative embodiment, the co-reactant in the gaseous form is a gas mixture comprising ammonia and hydrazine with a ratio of hydrazine to ammonia below 15% vol.

In an embodiment, the silicon containing compound is selected from the group consisting of trisilylamine (TSA) (SiH₃)₃N; disiloxane (DSO) (SiH₃)₂; disilylmethylamine (DSMA) (SiH₃)₂NMe; disilylethylamine (DSEA) (SiH₃)₂NEt; disilylisopropyllamine (DSIPA) (SiH₃)₂N(iPr); disilyltertbutylamine (DSTBA) (SiH₃)₂N(tBu); diethylaminosilane SiH₃NEt₂; diisopropylaminosilane SiH₃N(iPr)₂; ditertbutylaminosilaneSiH₃N(tBu)₂; silylpiperidine or piperidinosilane SiH₃(pip); silylpyrrolidine or pyrrolidinosilane SiH₃(pyr); bis(diethylamino)silane (BDEAS) SiH₂(NEt₂)₂; bis(dimethylamino)silane (BDMAS) SiH₂(NMe₂)₂; bis(tert-butylamino)silane (BTBAS) SiH₂(NHtBu)₂; bis(trimethylsilylamino)silane (BITS) SiH₂(NHSiMe₃)₂; bispiperidinosilane SiH₂(pip)₂; bispyrrolidinosilane SiH₂(pyr)₂; silyl triflate SiH₃(OTf); ditriflatosilane SiH₂(OTf)₂; and combinations thereof.

Also disclosed herein is a method of preparing a silicon nitride film comprising
introducing a silicon wafer to a reaction chamber;
introducing a silicon-containing compound to the reaction chamber;
purging the reaction chamber with an inert gas; and
introducing a nitrogen-containing co-reactant in gaseous form to the reaction chamber under conditions suitable for the formation of a monomolecular layer of a silicon nitride film on the silicon wafer.

Also disclosed herein is a method of preparing a silicon oxide film comprising
introducing a silicon wafer to a reaction chamber;
introducing a silicon-containing compound to the reaction chamber;
purging the reaction chamber with an inert gas; and

introducing a oxygen-containing co-reactant in gaseous form to the reaction chamber under conditions suitable for the formation of a monomolecular layer of a silicon oxide film on the silicon wafer.

### DETAILED DESCRIPTION OF THE PREFERRED EMBODIMENTS

Certain terms are used throughout the following description and claims to refer to particular system components. This document does not intend to distinguish between components that differ in name but not function.

In the following discussion and in the claims, the terms “including” and “comprising” are used in an open-ended fashion, and thus should be interpreted to mean “including, but not limited to . . . ”.

As used herein, the abbreviation, “Me,” refers to a methyl group; the abbreviation, “Et,” refers to an ethyl group; the abbreviation, “Pr,” refers to a propyl group; the abbreviation, “iPr,” refers to an isopropyl group;

Disclosed herein are methods for forming silicon-containing films on a substrate. In an embodiment, the method comprises providing a substrate in a reaction chamber; injecting into the reaction chamber at least one silicon-containing compound; injecting into the reaction chamber at least one co-reactant in the gaseous form; and reacting at a temperature below 550° C. the silicon-containing compound and gaseous co-reactant in order to obtain a silicon-containing film deposited onto the substrate. In an embodiment, the silicon-containing film comprises silicon oxide, alternatively silicon nitride, alternatively both silicon oxide and silicon nitride. The methods disclosed herein may be carried out at a temperature of equal to or less than 550° C. in order to maximize the reactivity of the silicon-containing compound with the co-reactant and substrate.

The silicon-containing compound may comprise aminosilanes, disilylamines, silanes, or combinations thereof.

In an embodiment, the silicon-containing compound comprises aminosilanes having the formula (R¹R² N)ₓSiH₄₋ₓ wherein R¹ and R² are independently H, C₁-C₆ linear, branched or cyclic carbon chain, or a silyl group such as trimethylsilyl, and x is either 1 or 2. Alternatively, the silicon-containing compound comprises aminosilanes having the formula LₓSiH₄₋ₓ wherein L is a C₃-C₁₂ cyclic amino ligand and x is either 1 or 2. Alternatively, the silicon-containing compound comprises disilylamines having the formula (SiH₃)₂NR wherein R is independently H, C₁-C₆ linear, branched or cyclic carbon chain. Alternatively, the silicon-containing compound comprises silanes having the formula (SiH₃)ₙR with n comprised between 1 and 4 and R being selected from the group consisting of H, N, NH, O, SO₃CF₃, CH₂, C₂H₄, SiH₂, SiH, and Si. Examples of silicon-containing compounds suitable for use in this disclosure include without limitation trisilylamine (TSA) (SiH₃)₃N; disiloxane (DSO) (SiH₃)₂; disilylmethylamine (DSMA) (SiH₃)₂NMe; disilylethylamine (DSEA) (SiH₃)₂NEt; disilylisopropyllamine (DSIPA) (SiH₃)₂N(iPr); disilyltertbutylamine (DSTBA) (SiH₃)₂N(tBu); diethylaminosilane SiH₃NEt₂; diisopropylaminosilane SiH₃N(iPr)₂; ditertbutylaminosilane SiH₃N(tBu)₂; silylpiperidine or piperidinosilane SiH₃(pip); silylpyrrolidine or pyrrolidinosilane SiH₃(pyr); bis(diethylamino)silane (BDEAS) SiH₂(NEt₂)₂; bis(dimethylamino)silane (BDMAS) SiH₂(NMe₂)₂; bis(tert-butylamino)silane (BTBAS) SiH₂(NHtBu)₂; bis(trimethylsilylamino)silane (BITS) SiH₂(NHSiMe₃)₂; bispiperidinosilane SiH₂(pip)₂; bispyrrolidinosilane SiH₂(pyr)₂; silyl triflate SiH₃(OTf); ditriflatosilane SiH₂(OTf)₂; or combinations thereof.

The co-reactant may comprise a material in the gaseous form such as an oxygen-containing gas, a nitrogen-containing gas, a gas containing both oxygen and nitrogen; or a mixture of gases having both oxygen-containing and nitrogen-containing compounds.

In an embodiment, the co-reactant comprises an oxygen-containing gas. Oxygen-containing gases suitable for use in this disclosure include without limitation ozone; molecular oxygen; vaporized water; hydrogen peroxide, or combinations thereof. In an embodiment, the co-reactant comprises a nitrogen-containing gas. Nitrogen-containing gases suitable for use in this disclosure include without limitation ammonia, nitrogen, hydrazine, or combinations thereof. In an embodiment the co-reactant comprises a gas or a mixture of gases wherein the gas and/or mixture of gases comprise both nitrogen and oxygen. Examples of such compounds suitable for use in this disclosure include without limitation nitric oxide and a mixture of ammonia and oxygen.

In an embodiment, the co-reactant comprises a mixture of ozone and oxygen. In such an embodiment, the ozone:oxygen ratio is below 30 percent volume (vol.), alternatively from 5% vol. to 20% vol. In some embodiments, the co-reactant comprises a mixture of ozone and oxygen that has been diluted into an inert gas such as for example nitrogen. In an embodiment, the co-reactant in the gaseous form is a gas mixture comprising ammonia and hydrazine with a ratio of hydrazine to ammonia below 15% vol., alternatively from 2% to 15% vol. In some embodiments, the co-reactant comprises an oxygen-containing and/or nitrogen-containing compound in the gaseous form which may react to form radicals when exposed to an ionized gas (i.e., plasma).

The co-reactant in the gaseous form may react with the silicon-containing compound to produce a material which deposits onto the substrate thus forming a silicon-containing film. For example, the co-reactant may comprise a mixture of ozone and oxygen; a gas comprising oxygen radicals formed from the excitation of oxygen in plasma; a mixture of ozone, oxygen and an inert gas such as nitrogen, argon, or helium; or combinations thereof. The ozone concentration in this gas mixture may be between 0.1% to 20% vol. Under the conditions of the reaction chamber, the oxygen-containing gas may oxidize the silicon-containing compound converting it into silicon oxide which deposits as a film onto the substrate.

Alternatively, the co-reactant comprises a nitrogen-containing gas and the nitrogen-containing gas nitridizes the silicon-containing compound and converts it into silicon nitride. This nitrogen-containing gas can be ammonia; a gas comprising nitrogen-containing radicals formed from the excitation of ammonia; a mixture of gaseous ammonia and an inert gas such as nitrogen, argon, or helium; or combinations thereof.

In an embodiment, a method of forming a silicon-containing film comprises providing a substrate in a reaction chamber. The reaction chamber may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the material to react and form the film. Any suitable substrate as known to one of ordinary skill in the art may be utilized. For example, the substrate may be a silicon wafer (or Silicon-on-Insulator (SOI) wafer) used for the manufacture of semiconductor devices, or layers deposited thereon, or a glass substrate used for the manufacture of liquid crystal display devices, or layers deposited thereon. In an embodiment, a semiconductor substrate on which a gate electrode has been formed is used as the substrate in particular when the silicon oxide film is used for the purpose of improving the gate breakdown voltage. In an embodiment, the substrate may be heated in the reaction chamber prior to introduction of any additional materials. The substrate may be heated to a temperature equal to or less than the reaction chamber temperature. For example, the substrate may be heated to a temperature of at least 50° C. and at most 550° C., alternatively between 200° C. and 400° C., alternatively between 250° C. and 350° C.

The method may further comprise introducing to the reaction chamber at least one silicon-containing compound. The silicon-containing may be introduced to the reaction chamber by any suitable technique (e.g., injection) and may be of the type previously described herein.

In an embodiment the method further comprises introduction of at least one co-reactant to the reaction chamber wherein the co-reactant may be in the gaseous form and of the type previously described herein. The co-reactant may be introduced to the reaction chamber utilizing any suitable methodology such as for example, injection. The silicon-containing compound and/or gaseous co-reactant may be introduced to the reactor in pulses. The silicon-containing compound may be pulsed into the reaction chamber from, for example, a cylinder when it is gaseous at ambient temperature. When the silicon-containing compound is a liquid at ambient temperature, as in the case of SiH₂(NEt₂)₂, it can be pulsed into the chamber using a bubbler technique. Specifically, a solution of the silicon-containing compound is placed in a container, heated as needed, entrained in an inert gas (for example, nitrogen, argon, helium) by bubbling the inert gas therethrough using an inert gas bubbler tube placed in the container, and is introduced into the chamber. A combination of a liquid mass flow controller and a vaporizer can also be used. A pulse of gaseous silicon-containing compound can be delivered into the reaction chamber, for example, for 0.1 to 10 seconds at a flow rate of 1.0 to 100 standard cubic centimeters per minute (sccm). The pulse of oxygen-containing gas can be delivered into the reaction chamber, for example, for 0.1 to 10 seconds at a flow rate of 10 to 1000 sccm.

The substrate, silicon-containing compound, and co-reactant may then be reacted in the reaction chamber in order to form a silicon-containing film that is deposited onto the substrate. In an embodiment, the reaction of the substrate, silicon-containing compound and co-reactant occurs at a temperature equal to or less than 550° C. for a time period sufficient to allow for formation of a silicon-containing film on the substrate. Deposition of the silicon-containing film onto the substrate is carried out under conditions suitable for the deposition method. Examples of suitable deposition methods include without limitation, conventional CVD, low pressure chemical vapor deposition (LPCVD), atomic layer deposition (ALD), pulsed chemical vapor deposition (P-CVD), plasma enhanced atomic layer deposition (PE-ALD), or combinations thereof. In an embodiment, the silicon-containing compound and/or the co-reactant are introduced to the reaction chamber discontinuously, for example by discontinuous injection. In an alternative embodiment, the silicon-containing compound and co-reactant are introduced to the reaction chamber simultaneously. In yet another embodiment, the silicon-containing compound and/or co-reactant is present on the surface of the substrate prior to introduction of another silicon-containing compound and/or co-reactant to the reaction chamber.

In an embodiment, the method further comprises introduction of an inert gas into the reaction chamber following the introduction of the silicon-containing compound, the co-reactant in gaseous form or both. Inert gases are known to one of ordinary skill in the art and include for example nitrogen, helium, argon, and combinations thereof. The inert gas may be introduced to the reaction chamber in sufficient quantity and for a time period sufficient to purge the reaction chamber.

Conditions in the reaction chamber may be adjusted by one of ordinary skill in the art with the aid of this disclosure to meet the needs of the process. In an embodiment, the pressure inside the reaction chamber may be between 0.1 to 1000 torr (13 to 1330 kPa) and alternatively between 0.1 to 10 torr (133 to 1330 kPa). Alternatively, the pressure inside the reaction chamber may be less than 500 torr, alternatively less than 100 torr, alternatively less than 2 torr.

In an embodiment, the methods described herein result in the formation of a silicon-containing film on the substrate. The thickness of the film may be increased by repeatedly subjecting the substrate to the previously described methodology until a user-desired film thickness is achieved. In an embodiment, the deposition rate of the silicon-containing film is equal to or greater than 1 Å/cycle.

In an embodiment, a method of producing a silicon-containing film on the substrate comprises introducing a substrate to a reaction chamber. After a substrate has been introduced to a reaction chamber, the gas within the chamber is first purged by feeding an inert gas (e.g., nitrogen) into the reaction chamber under reduced pressure at a substrate temperature of 50 to 550° C. Then, while at the same temperature and under reduced pressure, a pulse of a gaseous silicon-containing compound is delivered into the reaction chamber and a very thin layer of this silicon-containing compound is formed on the substrate by adsorption. This is followed by feeding an inert gas into the reaction chamber in order to purge therefrom unreacted (unadsorbed) silicon-containing compound, after which a pulse of one co-reactant in the gaseous form is delivered into the reaction chamber. The co-reactant in the gaseous form reacts to form a silicon-containing film comprising silicon oxide, silicon nitride or both. Inert gas may then be injected into the reaction chamber to purge unreacted products. In this embodiment, a silicon-containing film is formed on the substrate at the desired thickness, by repeating this sequence of inert gas purge, gaseous silicon-containing compound pulse, inert gas purge, and the co-reactant pulse.

Alternatively, after a substrate has been introduced into a reaction chamber, the gas within the chamber is first purged by feeding an inert gas into the reaction chamber under reduced pressure at a substrate temperature of 50 to 550° C. The co-reactant, which may consist of ammonia may then be introduced continuously. The silicon-containing compound (e.g., silane) is introduced sequentially and chemisorbed on the surface of the substrate. After purging the reaction chamber with an inert gas for a time period sufficient to evacuate the excess silane, a plasma is activated which results in the creation of excited species such as radicals. The silicon-containing compounds, gaseous co-reactant, and substrate may be contacted with the plasma for a time period sufficient to form a silicon-containing film of the type previously described herein. The excited species formed during the plasma activation have a very short lifetime and as a result will rapidly disappear following plasma deactivation. Consequently, purging of the reaction chamber with an inert gas subsequent to plasma deactivation may not be necessary. In this embodiment, a cycle then consists of one pulse of the silicon-containing compound, one pulse of purging gas, and one step wherein the plasma is activated.

The method according to the present disclosure for forming silicon-containing films is described in detail herein below.

In an embodiment, the method comprises the use of at least one gaseous co-reactant and an aminosilane of the general formula (R¹R²N)ₓSiH₄₋ₓ, where x is either 1 or 2, where R¹ and R² are independently H or a C₁-C₆ linear, branched or cyclic carbon chain and are independently introduced in the reactor continuously or by pulses such as by injection through an ALD process. The aminosilane may be an alkylaminosilane such as bis(diethylamino)silane (BDEAS), bis(dimethylamino)silane (BDMAS) or bis(trimethylsilylamino)silane (BITS). The aminosilane is adsorbed on the surface of the substrate. After a purge time sufficient to evacuate the aminosilane from the reactor using an inert gas, the gaseous co-reactant, which may consist of an oxygen/ozone gas mixture (typically: 5-20% vol. of ozone in oxygen), oxygen, moisture and/or hydrogen peroxide (H₂O₂), ammonia or a combination thereof, is introduced by pulses. A cycle then consists of one pulse of the aminosilane, one pulse of purging gas, one pulse of the gaseous co-reactant and one pulse of purging gas. The cycles may be repeated as necessary to achieve a targeted thickness. The number of cycles necessary will depend on the targeted thickness, taking into account the deposition rate per cycle obtained at given experimental conditions and may be determined by one of ordinary skill in the art with the benefits of this disclosure. In this embodiment, the deposition temperature can be from room temperature up to 500° C., with an operating pressure of between 0.1 and 100 Torr (13 to 13300 Pa). High quality films, with very low carbon and hydrogen contents, may be deposited between 200 and 550° C. at a pressure between 0.1-10 Torr (13 to 1330 Pa).

In another embodiment, the gaseous co-reactant, (e.g., ammonia) is introduced continuously. The aminosilane (e.g., BDEAS) may be introduced sequentially and chemisorbed on the surface of the substrate. After a purge time sufficient to evacuate the aminosilane in excess from the reactor using an inert gas, a plasma is activated, creating excited species such as radicals. After a time period sufficient to form a silicon-containing film, the plasma is deactivated. The excited species formed during the plasma activation have a very short lifetime and as a result will rapidly disappear following plasma deactivation. Consequently, purging of the reaction chamber with an inert gas subsequent to plasma deactivation may not be necessary. A cycle then consists of one pulse of the aminosilane, one pulse of purging gas, and one step wherein the plasma is activated.

In an embodiment, a method of forming a silicon-containing film on a substrate comprises the use of at least one gaseous co-reactant and at least one aminosilane having the formula LₓSiH₄₋ₓ, wherein L is a C₃-C₁₂ cyclic amino ligand and x is either 1 or 2. The gaseous co-reactant and aminosilane are independently introduced in the reactor continuously or by pulses such as for example injected through an ALD process. In an embodiment, the aminosilane is piperidinosilane SiH₃(pip), dipyrrolidinosilane SiH₂(pyr)₂, dipiperidinosilane SiH₂(Pip)₂ or pyrrolidinosilane SiH₃(pyr). The aminosilane is adsorbed on the surface of the substrate. Subsequently, an inert gas may be introduced to the reaction chamber for a time period sufficient to evacuate the aminosilane from the reactor using an inert gas. A gaseous co-reactant may then be introduced to the reaction chamber in pulses. The gaseous co-reactant may consist of an oxygen/ozone gas mixture (typically: 5-20% vol. of ozone in oxygen), oxygen, moisture and/or hydrogen peroxide (H₂O₂), ammonia or a combination thereof. A cycle then consists of one pulse of the aminosilane, one pulse of purging gas, one pulse of gaseous co-reactant and, one pulse of purging gas. The cycles may be repeated as necessary to achieve a targeted thickness. The number of cycles necessary will be determined by the targeted thickness, taking into account the deposition rate per cycle obtained at given experimental conditions and may be determined by one of ordinary skill in the art with the benefits of this disclosure. The deposition temperature can be as low as room temperature and up to 500° C., with an operating pressure of 0.1-100 Torr (13 to 13300 Pa). High quality films, with very low carbon and hydrogen contents, may be deposited between 200 and 550° C. at a pressure between 0.1-10 Torr (13 to 1330 Pa).

In another embodiment, the gaseous co-reactant, which may consist of ammonia is introduced continuously. The aminosilane (e.g., SiH₃(pip)) is introduced sequentially and chemisorbed on the surface of the substrate after which an inert gas may be used to purge the reaction chamber. The inert gas may be present for a time period sufficient to evacuate the aminosilane in excess from the reactor. After purging with the inert gas, a plasma may be activated thus creating excited species such as radicals. After time period sufficient to form a layer, the plasma is deactivated. The excited species formed during the plasma activation have a very short lifetime and as a result will rapidly disappear following plasma deactivation. Consequently, purging of the reaction chamber with an inert gas subsequent to plasma deactivation may not be necessary. A cycle then consists of one pulse of the aminosilane, one pulse of purging gas, and one step of plasma activation.

In an embodiment, a method of forming a silicon-containing film on a substrate comprises the use of at least one co-reactant in the gaseous form and at least one disilylamine having the formula (SiH₃)₂NR wherein R is independently H, C₁-C₆ linear, branched or cyclic carbon chain, are independently introduced in the reactor continuously or by pulses such as for example through an ALD process. In an embodiment the disilylamine is disilylethylamine (SiH₃)₂NEt, disilylisopropylamine (SiH₃)₂N(iPr) or disilyltert-butylamine (SiH₃)₂NtBu. The disilylamine is adsorbed on the surface of the substrate. A co-reactant in the gaseous form may then be introduced to the reaction chamber in pulses. The gaseous co-reactant may consist of an oxygen/ozone gas mixture (typically: 5-20% vol. of ozone in oxygen), oxygen, moisture and/or hydrogen peroxide (H₂O₂), ammonia or a combination thereof. A cycle then consists of one pulse of the disilylamine, one pulse of purging gas, one pulse co-reactant in the gaseous form and one pulse of purging gas. The cycles may be repeated as necessary to achieve a targeted thickness. The number of cycles necessary will be determined by the targeted thickness, taking into account the deposition rate per cycle obtained at given experimental conditions and may be determined by one of ordinary skill in the art with the benefits of this disclosure. The deposition temperature can be as low as room temperature and up to 500° C., with an operating pressure of 0.1-100 Torr (13 to 13300 Pa). High quality films, with very low carbon and hydrogen contents, may be deposited between 200 and 550° C. at a pressure between 0.1-10 Torr (13 to 1330 Pa).

In another embodiment, the co-reactant in the gaseous form, (e.g., ammonia) is introduced continuously. The disilylamine (e.g., (SiH₃)₂NEt) is introduced sequentially and chemisorbed on the surface of the substrate after which an inert gas may be used to purge the reaction chamber. The inert gas may be present for a time period sufficient to evacuate the disilylamine in excess from the reactor. After purging with the inert gas, a plasma may be activated thus creating excited species such as radicals. After time period sufficient to form the silicon-containing film, the plasma is deactivated. The excited species formed during the plasma activation have a very short lifetime and as a result will rapidly disappear following plasma deactivation. Consequently, purging of the reaction chamber with an inert gas subsequent to plasma deactivation may not be necessary. A cycle then consists of one pulse of the disilylamine, one pulse of purging gas, and one step of plasma activation.

In an embodiment, a method of forming a silicon-containing film on a substrate comprises the use of at least one co-reactant delivered in a gaseous form and a silane (silane, disilane, trisilane, trisilylamine) of the general formula (SiH₃)ₓR where x may vary from 1 to 4 and wherein R is selected from the group consisting of H, N, O, SO₃CF₃, CH₂, CH₂—CH₂, SiH₂, SiH, and Si with the possible use of a catalyst in the ALD regime. The aminosilane is adsorbed on the surface of the substrate. A gaseous co-reactant may then be introduced to the reaction chamber in pulses. The gaseous co-reactant may consist of an oxygen/ozone gas mixture (typically: 5-20% vol. of ozone in oxygen), oxygen, moisture and/or hydrogen peroxide (H₂O₂), ammonia or a combination thereof. A cycle then consists of one pulse of the silane, one pulse of purging gas, one pulse of co-reactant in the gaseous form and one pulse of purging gas. The cycles may be repeated as necessary to achieve a targeted thickness. The number of cycles necessary will be determined by the targeted thickness, taking into account the deposition rate per cycle obtained at given experimental conditions and may be determined by one of ordinary skill in the art with the benefits of this disclosure. The deposition temperature can be as low as room temperature and up to 500° C., with an operating pressure of 0.1-100 Torr (13 to 13300 Pa). High quality films, with very low carbon and hydrogen contents, are preferably deposited between 200 and 550° C. at a pressure between 0.1-10 Torr (13 to 1330 Pa).

In another embodiment, the co-reactant in the gaseous form, is introduced continuously to the reaction chamber. The silane is introduced sequentially and chemisorbed on the surface of the substrate after which an inert gas may be used to purge the reaction chamber. The inert gas may be present for a time period sufficient to evacuate the silane in excess from the reactor. After purging with the inert gas, a plasma may be activated thus creating excited species such as radicals. After time period sufficient to form the silicon-containing film, the plasma is deactivated. The excited species formed during the plasma activation have a very short lifetime and as a result will rapidly disappear following plasma deactivation. Consequently, purging of the reaction chamber with an inert gas subsequent to plasma deactivation may not be necessary. A cycle then consists of one pulse of the silane, one pulse of purging gas, one step where plasma is activated.

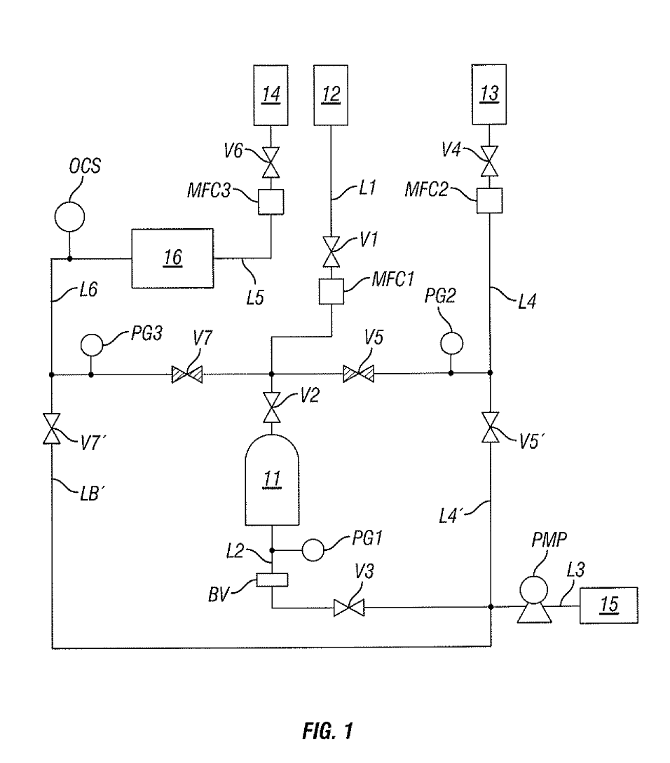

Referring to FIG. 1, a schematic diagram of a film-forming apparatus 10 used in the film-forming method described herein previously is shown. The film-forming apparatus 10 comprises a reaction chamber 11; an inert gas cylinder 12, which is a source of an inert gas feed (for example, nitrogen gas); an silicon-containing compound gas cylinder 13, which is a source of a feed of gaseous silicon-containing compound; and a co-reactant cylinder 14. In an embodiment, the film-forming apparatus 10 may be used as a single-wafer apparatus. In such an embodiment, a susceptor may be disposed within the reaction chamber 11 and one semiconductor substrate, for example, a silicon substrate, may be mounted thereon. A heater may be provided within the susceptor in order to heat the semiconductor substrate to the specified reaction temperature. In an alternative embodiment, the film-forming apparatus 10 may be used as a batch-type apparatus. In such an embodiment there may be from 5 to 200 semiconductor substrates held within the reaction chamber 11. The heater in a batch-type apparatus may have a different structure from the heater in a single-wafer apparatus.

The nitrogen gas cylinder 12 is in fluid communication with the reaction chamber 11 via a line L1. A shutoff valve V1 and a flow rate controller, for example, a mass flow controller MFC1, are disposed in the line L1. A shutoff valve V2 is also disposed in the line L1 and is in fluid communication with the reaction chamber 11.

The reaction chamber is also in fluid communication with a vacuum pump PMP via an exhaust line L2. A pressure gauge PG1, a butterfly valve BV for backpressure control, and a shutoff valve V3 are disposed in the line L2. The vacuum pump PMP is in fluid communication with a detoxification apparatus 15 via a line L3. The detoxification apparatus 15 may be, for example, a combustion-type detoxification apparatus or a dry-type detoxification apparatus, in correspondence to the gas species and levels thereof.

The silicon-containing compound gas cylinder 13 is in fluid communication with the line L1 via a line L4 wherein the line L4 connects the line L1 between the shutoff valve V2 and the mass flow controller MFC1. A shutoff valve V4, a mass flow controller MFC2, a pressure gauge PG2, and a shutoff valve VS are disposed in the line L4. The silicon-containing compound gas cylinder 13 is also in fluid communication with the line L2 via the line L4 and a branch line L4′. The branch line L4′ connects the line L2 between the vacuum pump PMP and the shutoff valve V3. A shutoff valve V5′ is disposed in the branch line L4′. The states of the shutoff valves V5 and V5′ are synchronized so that when one is open the other is closed.

The co-reactant cylinder 14 is in fluid communication with a highly reactive molecule generator 16 via a line LS. A shutoff valve V6 and a mass flow controller MFC3 are disposed in the line L5. The generator 16 is in fluid communication with the line L1 via a line L6 wherein the line L6 connects the line L1 between the shutoff valve V2 and the mass flow controller MFC1. A highly reactive molecule concentration sensor OCS, a pressure gauge PG3, and a shutoff valve V7 are disposed in the line L6. The generator 16 is also in fluid communication with the line L2 via the line L6 and a branch line L6′. The branch line L6′ connects the line L2 between the vacuum pump PMP and the shutoff valve V3. A shutoff valve V7′ is disposed in the branch line L6′. The states of the shutoff valves V7 and V7′ are synchronized so that when one is open the other is closed.

The generator 16 produces a mixed gas of co-reactant and highly reactive molecule that flows into the line L6. At a constant co-reactant gas feed flow rate, control of the highly reactive molecule concentration in the mixed gas depends on pressure and the power applied to the generator 16. The highly reactive molecule concentration is thereby controlled by measuring the highly reactive molecule level with a highly reactive molecule concentration sensor OCS and controlling the applied power and vessel pressure of the generator 16 based on this measured value.

In an embodiment, a method for forming silicon-containing films is described using the film-forming apparatus 10. In general, the method comprises the following steps: a nitrogen gas purge, a silicon-containing compound gas pulse, another nitrogen gas purge, and a co-reactant mixed gas pulse.

In an embodiment, the nitrogen gas purge step initiates by mounting a treatment substrate, for example, a semiconductor wafer, on the susceptor within the reaction chamber 11 and heating the semiconductor wafer to a temperature between 50° C. to 400° C. by using a temperature regulator incorporated in the susceptor. FIG. 1 shows the configuration of the film-forming apparatus 10 during the nitrogen gas purge step. As shown in FIG. 1, the shutoff valves VS and V7 are closed and the other shutoff valves V1 to V4, V6, V5′, and V7′ are all open. The closed control valves are shown with stripes in FIG. 1, while the open control valves are shown in white. Hereinafter, the status of the shutoff valves in the following description is shown in the same manner.

While exhausting the gas within the reaction chamber 11 through the exhaust line L2 by the operation of the vacuum pump PMP, nitrogen gas is introduced from the nitrogen gas cylinder 12 through the line L1 and into the reaction chamber 11. The feed flow rate of the nitrogen gas is controlled by the mass flow controller MFC1. A nitrogen gas purge is thereby carried out at a desired vacuum (for example, 0.1 to 1000 torr) by exhausting the gas within the reaction chamber 11 and feeding nitrogen gas into the reaction chamber 11 so that the interior of the reaction chamber 11 is substituted by nitrogen gas.

During the nitrogen gas purge step, the silicon-containing compound gas is continuously fed into the line L4 from the silicon-containing compound gas cylinder 13 under feed flow rate control by the mass flow controller MFC2. The shutoff valve V5 is closed and the shutoff valve V5′ is open, so that the Si containing compound gas is not fed into the reaction chamber 11 but rather is exhausted by feed through the lines L4 and L4′ into the exhaust line L2.

In addition, during the nitrogen gas purge step, at least one co-reactant delivered in the gaseous form is continuously fed through the line L5 from a cylinder 14 to the generator 16 to generate unstable molecules (ex: ozone, hydrazine) under feed flow rate controlled by the mass flow controller MFC3. A desired power level is applied to the generator 16, and at least one co-reactant delivered in the gaseous form containing unstable molecules at a desired concentration (the mixed gas) is fed into the line L6 from the generator 16. The unstable molecule level is measured with the concentration sensor OCS provided in the line L6, through which the mixed gas of unstable molecule(s) and at least one co-reactant delivered in the gaseous form flows. In an embodiment the reaction chamber comprises a device for formation of unstable molecules (e.g., radicals) with in the reaction chamber. For example, the reaction chamber may comprise one or more plasma sources which when activated generate a plasma within the reaction chamber. Further, the plasma source may have an adjustable power supply such that the plasma power may be adjusted to a user and/or process desired value. Such plasma sources and power supplies are known to one of ordinary skill in the art. Feedback control of the applied power and the vessel pressure of the generator 16 are carried out based on the resulting measured value. The shutoff valve V7 is closed and the shutoff valve V7′ is open, so that the mixed gas is not fed into the reaction chamber 11 but rather is exhausted by feed through the lines L6 and L6′ into the exhaust line L2.

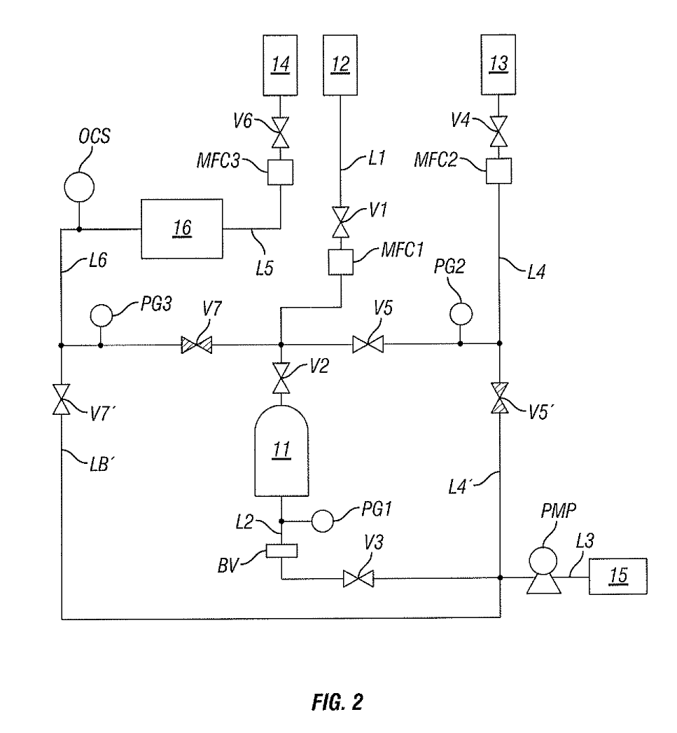

FIG. 2 shows the configuration of the film-forming apparatus 10 at the beginning of the Si containing compound gas pulse step. The shutoff valve VS′ is closed and, in synchrony with this operation, the shutoff valve V5 is opened. After a desired period of time, the status of each of these shutoff valves VS and V5 ′ is then reversed. During the interval in which the shutoff valve V5 is open, silicon-containing compound gas from the silicon-containing compound gas cylinder 13 is fed under flow rate control from the line L4 into the line L1 and is pulsed into the reaction chamber 11 along with nitrogen gas. This pulse results in the adsorption of an approximately monomolecular layer of the silicon-containing compound on the heated surface of the semiconductor wafer mounted on the susceptor in the reaction chamber 11.

After the silicon-containing compound gas pulse has been delivered, a nitrogen gas purge is carried out by closing the shutoff valves VS and opening the shutoff valve VS′, as shown in FIG. 1. After the nitrogen gas purge, the unreacted silicon-containing compound remaining in the reaction chamber 11 is exhausted by means of the nitrogen gas and the interior of the reaction chamber 11 is again substituted by nitrogen gas.

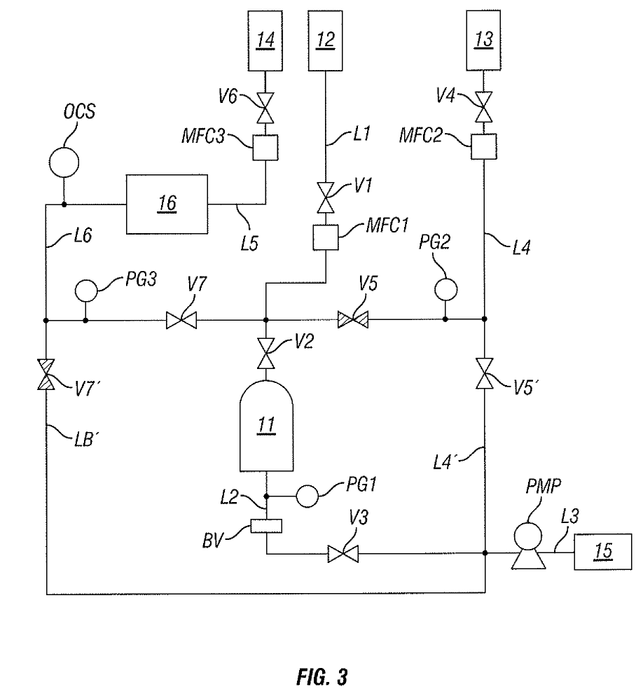

FIG. 3 shows the configuration of the film-forming apparatus 10 at the beginning of the co-reactant mixed gas pulse. The shutoff valve V7′ is closed and, in synchrony with this operation, the shutoff valve V7 is opened. After a desired period of time, the status of each of these shutoff valves V7 and V7′ is then reversed. During the interval in which the shutoff valve V7 is open, the mixed gas of unstable molecule(s) and at least one co-reactant delivered in the gaseous form is fed from the line L6 into the line L1 and is pulsed into the reaction chamber 11 along with nitrogen gas. As a result of this pulse, the silicon-containing compound adsorbed on the heated surface of the semiconductor wafer mounted on the susceptor in the reaction chamber 11 reacts with the mixed gas of unstable molecule(s) and at least one co-reactant delivered in the gaseous form. The reaction of the silicon-containing compound and the mixed gas of unstable molecule(s) and at least one co-reactant results in the formation on the surface of the semiconductor wafer of a silicon-containing film in the form of an approximately monomolecular layer.

A silicon-containing film of desired thickness is formed on the surface of the semiconductor wafer by repeating a cycle comprising the steps of 1) nitrogen gas purge, 2) silicon-containing compound gas pulse, 3) nitrogen gas purge and 4) co-reactants mixed gas pulse. After delivery of the co-reactants mixed gas pulse, a nitrogen gas purge is carried out by closing the shutoff valves V7 and opening the shutoff valves V7′, as shown in FIG. 1. After the nitrogen gas is purged, reaction by-products and the mixed gas of unstable molecule(s) and at least one co-reactant delivered in the gaseous form remaining in the reaction chamber 11 are exhausted by means of the nitrogen gas and the interior of the reaction chamber 11 is again substituted by nitrogen gas.

As described above, a silicon-containing compound that is gaseous at ambient temperature is used as an example for formation using the film-forming apparatus shown in FIGS. 1 to 3. In an alternative embodiment, a silicon-containing compound that is liquid at ambient temperature, such as BDEAS, may be used. In such an embodiment, gaseous silicon-containing compound may still be introduced into the reaction chamber 11 using a bubbler procedure. For example, a bubbler may be provided in place of the silicon-containing compound gas cylinder 13 shown in FIGS. 1 to 3. The bubbler may be connected to a branch line branched off upstream from the valve V1 in the nitrogen gas-carrying line L1 wherein nitrogen from gas cylinder 12 may be bubbled through a liquid silicon-containing compound and fed to reaction chamber 11 so that the method as described previously herein may be carried out.

In an embodiment, one reactant may be introduced continuously while the other can be introduced by pulses (pulsed-CVD regime). In such an embodiment, the formation of a silicon-containing film e.g., silicon oxide film) in the form of an approximately monomolecular layer occurs by first inducing the adsorption of the silicon-containing compound. This is accomplished through the delivery of a pulse of silicon-containing compound gas onto the surface of the treatment substrate which has been heated as described herein previously. An inert gas (for example, nitrogen gas) is then used to purge the reaction chamber prior to delivering a pulse of co-reactant mixed gas (for example, an ozone+oxygen mixed gas). The thorough oxidation of the silicon-containing compound adsorbed on the surface of the treatment substrate by the strong oxidizing action of the ozone in the mixed gas enables the formation of a silicon-containing film (e.g., silicon oxide film) in the form of an approximately monomolecular layer. In addition, the inert gas purge (for example, nitrogen gas purge) after the oxidation reaction may prevent the adsorption of moisture within the reaction chamber by the silicon oxide film that has been formed.

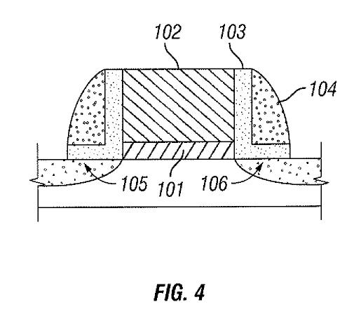

FIG. 4 illustrates a side view of a metal oxide semiconductor (MOS) transistor 100 comprising a silicon-containing layer (such as SiO2 layer) of the type disclosed herein. The MOS transistor 100 comprises wafer 107, drain 105, source 106, gate 101, metal electrode 102 and silicon-containing films 103. On the wafer 107, the gate 101 is located above and in between the drain 105 and the source 106. The metal electrode 102 is deposited above the gate 101. Silicon-containing films 103 such as SiO₂ films are laterally placed on the lateral ends of the gate 101 and the metal gate electrode 102. Silicon-containing films 103 are also deposited on the top of the source 106 and the drain 105.

In an embodiment, the methodology disclosed herein results in the production of a silicon-containing film, particularly when deposited using the ALD process with nitrogen purge between each injection, having a very high conformality (i.e., the ability to deposit uniform films in the top and the bottom of a trench). Such films may be useful in gap-fill applications or for capacitors electrode for dynamic random access memory DRAM, i.e., films which fill out all the cavities on a surface and provide a uniform Si-containing layer.

To further illustrate various illustrative embodiments of the present invention, the following examples are provided.

### EXAMPLES

The film-forming apparatus 10 shown in FIGS. 1 to 3 was used in the following Examples 1A-F.

### Example 1A

A silicon wafer was positioned on the susceptor in the reaction chamber 11 and the wafer was heated to 500° C. A silicon oxide film was formed by repeating a cycle comprising the steps of 1) nitrogen gas purge, 2) silicon-containing compound gas pulse, 3) nitrogen gas purge, and 4) ozone+oxygen mixed gas pulse as described herein previously using the following conditions:

1) Nitrogen gas purge
pressure within the reaction chamber: 3 torr
nitrogen gas feed flow rate: 130 sccm
nitrogen gas purge time: 6 seconds

2) Silicon-containing compound gas pulse
pressure within the reaction chamber: 3 torr
Si compound gas: bis(diethylamino)silane (BDEAS) gas
BPDEAS gas feed flow rate: 2 sccm
BDEAS pulse time: 1 second

3) Nitrogen gas purge
pressure within the reaction chamber: 3 torr
nitrogen gas feed flow rate: 130 sccm
nitrogen gas purge time: 6 seconds

4) Ozone+oxygen mixed gas pulse
pressure within the reaction chamber: 3 torr
feed flow rate of the ozone+oxygen mixed gas (5% ozone conc.): 20 sccm
mixed gas pulse time: 2 seconds

### Example 1B

A silicon wafer was positioned on the susceptor in the reaction chamber 11 and the wafer was heated to 550° C. A silicon nitride film was formed by repeating a cycle comprising the steps of 1) nitrogen gas purge, 2) silicon-containing compound gas pulse, 3) nitrogen gas purge, and 4) hydrazine+ammonia mixed gas pulse as described herein previously using the following conditions:

1) Nitrogen gas purge
pressure within the reaction chamber: 3 torr
nitrogen gas feed flow rate: 130 sccm
nitrogen gas purge time: 6 seconds

2) silicon-containing compound gas pulse
pressure within the reaction chamber: 3 torr silicon-containing compound gas: bis(diethylamino)silane (BDEAS) gas
BDEAS gas feed flow rate: 2 sccm
BDEAS pulse time: 1 second

3) Nitrogen gas purge
pressure within the reaction chamber: 3 torr
nitrogen gas feed flow rate: 130 sccm
nitrogen gas purge time: 6 seconds

4) Hydrazine+ammonia mixed gas pulse
pressure within the reaction chamber: 3 torr
feed flow rate of the hydrazine+ammonia mixed gas (3% ozone conc.): 20 sccm
mixed gas pulse time: 2 seconds

### Example 1C

A silicon wafer was positioned on the susceptor in the reaction chamber 11 and the wafer was heated to 500° C. A silicon oxide film was formed by repeating a cycle comprising the steps of 1) nitrogen gas purge, 2) silicon-containing compound gas pulse, 3) nitrogen gas purge, and 4) oxygen pulse while switching on a plasma as described herein previously using the following conditions:

1) Nitrogen gas purge
pressure within the reaction chamber: 3 torr
nitrogen gas feed flow rate: 130 seem
nitrogen gas purge time: 6 seconds

2) silicon-containing compound gas pulse
pressure within the reaction chamber: 3 torr
Si compound gas: bis(diethylamino)silane (BDEAS) gas
BDEAS gas feed flow rate: 2 sccm
BDEAS pulse time: 1 second

3) Nitrogen gas purge
pressure within the reaction chamber: 3 torr
nitrogen gas feed flow rate: 130 sccm
nitrogen gas purge time: 6 seconds

4) Oxygen pulse
pressure within the reaction chamber: 3 torr
feed flow rate of the oxygen mixed gas: 20 sccm
oxygen pulse time: 2 seconds
plasma power: 100 W

### Example 1D

A silicon wafer was positioned on the susceptor in the reaction chamber 11 and the wafer was heated to 550° C. A silicon nitride film was formed by repeating a cycle comprising the steps of 1) nitrogen gas purge, 2) silicon-containing compound gas pulse, 3) nitrogen gas purge, and 4) ammonia pulse while switching on a plasma as described herein previously using the following conditions:

1) Nitrogen gas purge
pressure within the reaction chamber: 3 torr
nitrogen gas feed flow rate: 130 sccm
nitrogen gas purge time: 6 seconds

2) silicon-containing compound gas pulse
pressure within the reaction chamber: 3 torr
silicon-containing compound gas: bis(diethylamino)silane (BDEAS) gas
BDEAS gas feed flow rate: 2 sccm
BDEAS pulse time: 1 second

3) Nitrogen gas purge
pressure within the reaction chamber: 3 torr
nitrogen gas feed flow rate: 130 sccm
nitrogen gas purge time: 6 seconds

4) Ammonia pulse
pressure within the reaction chamber: 3 torr
feed flow rate of the ammonia: 20 sccm
mixed gas pulse time: 2 seconds
plasma power: 350 W

### Example 1E

A silicon wafer was positioned on the susceptor in the reaction chamber 11 and the wafer was heated to 150° C. A silicon oxide film was formed by continuously flowing oxygen in the reaction chamber 11 and repeating a cycle comprising the steps of 1) silicon-containing compound gas pulse, 2) nitrogen gas purge, and 3) switching on a plasma as described herein previously using the following conditions:

1) silicon-containing compound gas pulse
pressure within the reaction chamber: 1 torr
Silicon-containing compound gas: bis(diethylamino)silane (BDEAS) gas
BDEAS gas feed flow rate: 2 sccm
BDEAS pulse time: 1 second

2) Nitrogen gas purge
pressure within the reaction chamber: 1 torr
nitrogen gas feed flow rate: 130 sccm
nitrogen gas purge time: 6 seconds

3) Plasma on
pressure within the reaction chamber: 1 torr
plasma on time: 2 seconds
plasma power: 100 W

### Example 1F

A silicon wafer was positioned on the susceptor in the reaction chamber 11 and the wafer was heated to 500° C. A silicon nitride film was formed by continuously flowing ammonia at a rate of 20 sccm in the reaction chamber 11 and repeating a cycle comprising the steps of 1) silicon-containing compound gas pulse, 2) nitrogen gas purge, and 3) switching on a plasma as described herein previously using the following conditions:

1) silicon-containing compound gas pulse
pressure within the reaction chamber: 1 torr
silicon-containing compound gas: bis(diethylamino)silane (BDEAS) gas
BDEAS gas feed flow rate: 2 sccm
BDEAS pulse time: 1 second

2) Nitrogen gas purge
pressure within the reaction chamber: 1 torr
nitrogen gas feed flow rate: 130 sccm
nitrogen gas purge time: 6 seconds

3) Plasma on
pressure within the reaction chamber: 1 torr
plasma on time: 2 seconds
plasma power: 350 W

### Example 2A-F

A silicon-containing film was formed using method similar to that described in Examples 1A-F, however, the silicon water was heated by placing the silicon wafer on the susceptor within the reaction chamber 11 that was heated to 400° C.

### Example 3A-F

A silicon-containing film was formed using a method similar to that described in Examples 1A-F, however, the silicon water was heated by placing the silicon wafer on the susceptor within the reaction chamber 11 that was heated to 300° C.

The thickness of the silicon-containing film was measured at each cycle in Examples 1 to 3 (Example 1 was carried through 50 cycles). A silicon-containing film could be formed in Examples 1 to 3 with good thickness control, without an incubation period, at a rate of about 0.8-1.5 Å/cycle.

In addition, FT-IR analysis was carried out on the silicon-containing film produced in Example 3 after 200 cycles (wafer temperature: 300° C.).

### Example 4

ALD deposition of SiO₂ films using BDEAS and ozone was investigated. Films were successfully deposited on silicon and iridium by ALD using BDEAS and a mixture of ozone/oxygen, using the film-forming apparatus as shown in FIGS. 1-3.

The chamber was a hot-wall reactor heated by conventional heater. The ozonizer produced the ozone and its concentration was approximately 150 g/m³ at −0.01 MPaG. BDEAS (Bis(diethylamino)silane, SiH₂(NEt₂)₂) was introduced to the reaction chamber 11 by the bubbling of an inert gas (nitrogen) into the liquid aminosilane. The experimental conditions were as follows:
7.0 seem O₃
93 seem O₂
BDEAS: 1 sccm i(n the range of 1 to 7 sccm)
N₂: 50 sccm
Temperature ranging between 200° C. and 400° C.
Operating pressure: 1 Torr (in the range of 0.1 to 5 Torr)
Purge and pulse times were typically set at 5 seconds each.
The number of cycles was typically set to 600 cycles.

Experiments were performed in order to determine films characteristics such as deposition rate, deposition temperature, film quality, and film composition.

SiO₂ films were deposited onto the Si wafer at 200° C., 250° C., 300° C., 350° C., and 400° C. The deposited films did not include carbon or nitrogen according to an in-depth Auger analysis.

The number of cycles for the deposition of SiO₂ films were varied (e.g., 350, 600, and 900 cycles deposition tests) and the deposited SiO₂ films were checked so that there was negligible incubation time. Depositions on iridium were performed in order to observe the possible oxidation of the metal electrode. The Auger profile shows a sharp interface between ALD SiO₂ and iridium substrate, which suggested that no metal oxidation was observed.

### Example 5

ALD deposition of SiO₂ films using silylpyrrolidine and ozone was investigated using conditions similar to those described in Example 4. High quality films were obtained at a deposition rate of 1.6 Å/cycle at 1 Torr between 300° C. and 350° C.

### Example 6

ALD deposition of SiO₂ films using diethylaminosilane and ozone was investigated using conditions similar to those described in Example 4. High quality films were obtained at a deposition rate of 1.4 Å/cycle at 1 Torr between 250° C. and 300° C.

### Example 7

ALD deposition of SiN films using silylpyrrolidine and hydrazine was investigated. Films were successfully deposited onto a silicon wafer using ALD by alternatively introducing silylpyrrolidine, N₂, and a hydrazine/ammonia mixture.

The chamber was a hot-wall tubular reactor heated by a conventional heater. Silylpyrrolidine was introduced to furnace by the bubbling of an inert gas (nitrogen) into the liquid aminosilane. The experimental conditions were as follows:
3.2 sccm hydrazine
96.8 sccm ammonia
silylpyrrolidine: 1 sccm
N₂: 50 sccm
Temperature ranging between 300° C. and 550° C.
Operating pressure: 1 Torr (in the range of 0.1 to 5 Torr)
Purge and pulse times were typically set at 5 seconds each.
The number of cycles was typically set to 600 cycles.

The resulting SiN films were obtained on a silicon wafer and did not contain carbon or nitrogen according to an in-depth Auger analysis.

### Example 8

Plasma Enhanced ALD (PEALD) deposition of SiN films using BDEAS and ammonia was investigated. Films were successfully deposited on silicon using ALD by continuously flowing ammonia and alternatively introducing BDEAS, purging with N₂, and switching on plasma power. Since the ammonia-derived species have a very short lifetime after the extinction of the plasma, no purge after the plasma is switched off was needed, thereby reducing the cycle time and improving the throughput.

The chamber was a 6″ PEALD commercial reactor. BDEAS was introduced to furnace by the bubbling of an inert gas (nitrogen) into the liquid aminosilane. The experimental conditions were as follows:
100 sccm ammonia
BDEAS: 1 sccm
N₂: 50 sccm
Temperature ranging between 300° C. and 550° C.
Operating pressure: 1 Torr
Plasma power: 350 W
Purge and pulse times were typically set at 5 seconds each.
The number of cycles was typically set to 400 cycles.

The resulting SiN films were obtained on a silicon wafer and did not contain carbon or nitrogen according to an in-depth Auger analysis.

### Example 9

PEALD deposition of SiO₂ films using BDEAS and oxygen was investigated. Films were successfully deposited on silicon using ALD by continuously flowing oxygen and alternatively introducing BDEAS, purging with N₂, and switching on plasma power. Since the oxygen-derived species have a very short lifetime after the extinction of the plasma, no purge after the plasma is switched off is needed, reducing the cycle time and therefore improving the throughput.

The chamber was a 6″ PEALD commercial reactor. BDEAS was introduced to furnace by the bubbling of an inert gas (nitrogen) into the liquid aminosilane. The experimental conditions were as follows:
O₂:100 sccm
BDEAS: 1 sccm
N₂: 50 sccm
Temperature ranging between 100° C. and 400° C.
Operating pressure: 1 Torr
Plasma power: 100 W
Purge and pulse times were typically set at 5 seconds each.
The number of cycles was typically set to 400 cycles.

SiO₂ films were obtained on a silicon wafer and did not contain carbon or nitrogen according to an in-depth Auger analysis.

### Example 10

PEALD deposition of SiN films using BDEAS and nitrogen was investigated. Films were successfully deposited on silicon using ALD by continuously flowing nitrogen and alternatively introducing BDEAS, purging with N₂, and switching on plasma power. Since the nitrogen-derived species have a very short lifetime after the extinction of the plasma, no purge after the plasma is switched off was needed, reducing the cycle time and therefore improving the throughput.

The chamber was a 6″ PEALD commercial reactor. BDEAS was introduced to furnace by the bubbling of an inert gas (nitrogen) into the liquid aminosilane. The experimental conditions were as follows:
BDEAS: 1 sccm
N₂: 150 sccm
Temperature ranging between 300° C. and 550° C.
Operating pressure: 1 Torr
Plasma power: 450 W
Purge and pulse times were typically set at 5 seconds each.
The number of cycles was typically set to 500 cycles.

The resulting SiN films were obtained on a silicon wafer and did not contain carbon or nitrogen according to an in-depth Auger analysis.

### Example 11

CVD deposition of SiO₂ films using silylpyrrolidine and H₂O₂ was investigated. Films were successfully deposited on silicon using CVD by continuously flowing silylpyrrolidine and H₂O₂ using the following conditions:
silylpyrrolidine: 1 sccm
H₂O₂: 10 sccm
N₂: 20 sccm
Temperature ranging between 100° C. and 500° C.
Operating pressure: 300 Torr

SiO₂ films were obtained on a silicon wafer and did not contain carbon or nitrogen according to an in-depth Auger analysis.

While embodiments of the invention have been shown and described, modifications thereof can be made by one skilled in the art without departing from the spirit and teachings of the invention. The embodiments described and the examples provided herein are exemplary only, and are not intended to be limiting. Many variations and modifications of the invention disclosed herein are possible and are within the scope of the invention. Accordingly, the scope of protection is not limited by the description set out above, but is only limited by the claims which follow, that scope including all equivalents of the subject matter of the claims.

What is claimed is:

1. A method of forming a silicon-containing film comprising:
a) providing a substrate in a reaction chamber,
b) injecting into the reaction chamber at least one silicon-containing compound;
c) injecting into the reaction chamber at least one co-reactant in the gaseous form; and
d) reacting the substrate, silicon-containing compound, and co-reactant in the gaseous form at a temperature equal to or less than 550° C. to obtain a silicon-containing film deposited onto the substrate.

2. The method of claim 1 wherein the silicon-containing compound comprises an aminosilane, a disiliylamine, a silane, or combinations thereof.

3. The method of claim 2 wherein the aminosilane comprises a compound having the formula (R¹R² N)ₓSiH₄₋ₓ wherein R¹ and R² are independently H, C₁-C₆ linear, branched or cyclic carbon chain, or a silyl group such as trimethylsilyl, and x is either 1 or 2.

4. The method of claim 2 wherein the aminosilane comprises a compound having the formula LₓSiH₄₋ₓ wherein L is a C₃-C₁₂ cyclic amino ligand and x is either 1 or 2.

5. The method of claim 2 wherein the disilylamine comprises a compound disilylamines having the formula (SiH₃)₂NR wherein R is independently H, C₁-C₆ linear, or a branched or cyclic carbon chain.

6. The method of claim 2 wherein the silane comprises a compound having the formula (SiH₃)ₙR with n comprised between 1 and 4, R being selected from the group consisting of H, N, NH, O, SO₃CF₃, CH₂, C₂H₄, SiH₂, SiH and Si.

7. The method of claim 1 wherein the co-reactant comprises an oxygen-containing gas, a nitrogen-containing gas, a gas comprising both oxygen and nitrogen, or a mixture of gases comprising both oxygen and nitrogen.

8. The method of claim 7 wherein the oxygen-containing gas comprises ozone, oxygen, water vapor, hydrogen peroxide, or combinations thereof.

9. The method of claim 7 wherein the nitrogen-containing gas comprises ammonia, nitrogen, hydrazine, or combinations thereof.

10. The method of claim 7 wherein the mixture of gases comprises ammonia and oxygen.

11. The method of claim 1 wherein the co-reactant comprises nitric oxide.

12. The method of claim 1 further comprising generating a co-reactant comprising oxygen or nitrogen radicals.

13. The method of claim 12 wherein generating the co-reactant comprises exposing an oxygen-containing or nitrogen-containing compound to a plasma under conditions suitable for the generation of oxygen or nitrogen radicals.

14. The method of claim 1 further comprising purging the reaction chamber with an inert gas after steps a, b, c, d, or combinations thereof.

15. The method of claim 14 wherein the inert gas comprises nitrogen, argon, helium, or combinations thereof.

16. The method of claim 1 further comprising repeating steps b) to d) until the desired silicon-containing film thickness is obtained.

17. The method of claim 1 further comprising heating the substrate in the reaction chamber after its introduction to the reaction chamber prior to carrying out steps b), c), and/or d).

18. The method of claim 17 wherein the substrate is heated to a temperature equal to or less than the reaction chamber temperature.

19. The method of claim 1 wherein the substrate comprises a silicon wafer (or SOI) used for the manufacture of semiconductor devices, layers deposited thereon, a glass substrate used for the manufacture of liquid crystal display devices, or layers deposited thereon.

20. The method of claim 1 wherein steps b), c), or both is carried out by discontinued injection of at least one of the compounds and/or gases.

21. The method of claim 1 wherein pulsed chemical vapor deposition or atomic layer deposition is carried out in the reaction chamber.

22. The method of claim 1 wherein simultaneous injection of the silicon-containing compound and the co-reactant in the gaseous form is carried out in the reaction chamber.

23. The method of claim 1 wherein alternate injection of the silicon-containing compound and the co-reactant in the gaseous form is carried out in the reaction chamber.

24. The method of claim 1 wherein the silicon-containing compound or the co-reactant in the gaseous form is adsorbed on the surface of the substrate prior to the injection of another compound and/or at least one co-reactant in the gaseous form.

25. The method of claim 1 wherein the silicon-containing film is formed at a deposition rate of equal to or greater than 1 Å/cycle.

26. The method of claim 1 wherein the reaction chamber pressure is at 0.1 to 1000 torr (13 to 1330 kPa).

27. The method of claim 1 wherein the co-reactant in the gaseous form is a gas mixture comprising oxygen and ozone with a ratio of ozone to oxygen below 20% vol.

28. The method of claim 1 wherein the co-reactant in the gaseous form is a gas mixture comprising ammonia and hydrazine with a ratio of hydrazine to ammonia below 15% vol.

29. The method of claim 1 wherein the silicon containing compound is selected from the group consisting of trisilylamine (TSA) (SiH₃)₃N; disiloxane (DSO) (SiH₃)₂; disilylmethylamine (DSMA) (SiH₃)₂NMe; disilylethylamine (DSEA) (SiH₃)₂NEt; disilylisopropyllamine (DSIPA) (SiH₃)₂N(iPr) ; disilyltertbutylamine (DSTBA) (SiH₃)₂N(tBu); diethylaminosilane SiH₃NEt₂; diisopropylaminosilane SiH₃N(iPr)₂; ditertbutylaminosilaneSiH₃N(tBu)₂; silylpiperidine or piperidinosilane SiH₃(pip); silylpyrrolidine or pyrrolidinosilane SiH₃(pyr); bis(diethylamino)silane (BDEAS) SiH₂(NEt₂)₂; bis(dimethylamino)silane (BDMAS) SiH₂(NMe₂)₂; bis(tert-butylamino)silane (BTBAS) SiH₂(NHtBu)₂; bis(trimethylsilylamino)silane (BITS) SiH₂(NHSiMe₃)₂; bispiperidinosilane SiH₂(pip)₂; bispyrrolidinosilane SiH₂(pyr)₂; silyl triflate SiH₃(OTf); ditriflatosilane SiH₂(OTf)₂; and combinations thereof.

30. The method of claim 1 further comprising generating a plasma in the reaction chamber.

31. The method of claim 1 further comprising feeding radicals to the reaction chamber, generating radicals in the reaction chamber, or both.

32. A method of preparing a silicon nitride film comprising
introducing a silicon wafer to a reaction chamber;
introducing a silicon-containing compound to the reaction chamber;
purging the reaction chamber with an inert gas; and
introducing a nitrogen-containing co-reactant in gaseous form to the reaction chamber under conditions suitable for the formation of a monomolecular layer of a silicon nitride film on the silicon wafer.

33. A method of preparing a silicon oxide film comprising
introducing a silicon wafer to a reaction chamber;
introducing a silicon-containing compound to the reaction chamber;
purging the reaction chamber with an inert gas; and introducing a oxygen-containing co-reactant in gaseous form to the reaction chamber under conditions suitable for the formation of a monomolecular layer of a silicon oxide film on the silicon wafer.
